(19) United States
(12) Patent Application Publication
(10) Pub. No.: US 2011/0104393 A1
(43) Pub. Date: May 5, 2011

(54) PLASMA ION IMPLANTATION PROCESS FOR PATTERNED DISC MEDIA APPLICATIONS

(75) Inventors: Martin A. Hilkene, Gilroy, CA (US); Matthew D. Scotney-Castle, Morgan Hill, CA (US); Roman Gouk, San Jose, CA (US); Steven Verhaverbeke, San Francisco, CA (US)

(73) Assignee: APPLIED MATERIALS, INC., Santa Clara, CA (US)

(21) Appl. No.: 12/939,713

(22) Filed: Nov. 4, 2010

Related U.S. Application Data
(60) Provisional application No. 61/258,027, filed on Nov. 4, 2009.

(51) Int. Cl. C23C 14/04

(52) U.S. Cl. 427/526; 118/723 VE

(57) ABSTRACT

Processes and apparatus of forming patterns including magnetic and non-magnetic domains on a magnetically susceptible surface on a substrate are provided. In one embodiment, a method of forming a pattern of magnetic domains on a magnetically susceptible material disposed on a substrate includes exposing a first portion of a magnetically susceptible layer to a plasma formed from a gas mixture, wherein the gas mixture includes at least a halogen containing gas and a hydrogen containing gas for a time sufficient to modify a magnetic property of the first portion of the magnetically susceptible layer exposed through a mask layer from a first state to a second state.

### CROSS-REFERENCE TO RELATED APPLICATIONS

This application claims benefit of U.S. Provisional Application Ser. No. 61/258,027 filed Nov. 4, 2009 (Attorney Docket No. APPM/14593L), which is incorporated by reference in its entirety.

### FIELD

Embodiments of the invention relate to hard-disk drive (HDD) media, and apparatus and methods for making hard-disk drive media. More specifically, embodiments of the invention relate to methods and apparatus for forming a patterned magnetic disc medium for a hard-disk drive.

### BACKGROUND

Hard-disk drives (HDD) are the storage medium of choice for computers and related devices. They are found in most desktop and laptop computers, and may also be found in a number of consumer electronic devices, such as media recorders and players, and instruments for collecting and recording data. Hard- disk drives are also deployed in arrays for network storage.

Hard-disk drives store information magnetically. The disk in a hard-disk drive is configured with magnetic domains that are separately addressable by a magnetic head. The magnetic head moves into proximity with a magnetic domain and alters the magnetic properties of the domain to record information. To recover the recorded information, the magnetic head moves into proximity with the domain and detects the magnetic properties of the domain. The magnetic properties of the domain are generally interpreted as corresponding to one of two possible states, the “0” state and the “1” state. In this way, digital information may be recorded on the magnetic medium and recovered thereafter.

The magnetic medium in a hard-disk drive is generally a glass, composite glass/ceramic, or metal substrate, which is generally non-magnetic, with a magnetically susceptible material deposited thereon. The magnetically susceptible layer is generally deposited to form a pattern, such that the surface of the disk has areas of magnetic susceptibility interspersed with areas of magnetic inactivity. The non-magnetic substrate is usually topographically patterned, and the magnetically susceptible material deposited by spin-coating or electroplating. The disk may then be polished or planarized to expose the non-magnetic boundaries around the magnetic domains. In some cases, the magnetic material is deposited in a patterned way to form magnetic grains or dots separated by a non-magnetic area.

Such methods are expected to yield storage structures capable of supporting data density up to about 1 TB/in², with individual domains having dimensions as small as 20 nm. Where domains with different spin orientations meet, there is a region referred to as a Bloch wall in which the spin orientation goes through a transition from the first orientation to a second orientation. The width of this transition region limits the areal density of information storage because the Bloch wall occupies an increasing portion of the total magnetic domain.

To overcome the space limits due to Bloch wall width in continuous magnetic thin films, the domains can be physically separated by a non-magnetic region (which can be narrower than the width of a Bloch wall in a continuous magnetic thin film). Conventional approaches to create discrete magnetic and non-magnetic areas on a medium have focused on forming single bit magnetic domains that are completely separate from each other, either by depositing the magnetic domains as separate islands or by removing material from a continuous magnetic film to physically separate the magnetic domains. A substrate may be masked and patterned, and a magnetic material deposited over exposed portions, or the magnetic material may be deposited before masking and patterning, and then etched away in exposed portions. In either case, the topography of the substrate is altered by the residual pattern of the magnetic regions. Because the read-write head of a typical hard-disk drive may fly as close as 2 nm from the surface of the disk, these topographic alterations can become limiting. Thus, there is a need for a process or method of patterning magnetic media to form magnetic and non-magnetic areas on a medium that has high resolution and does not alter the topography of the media, and an apparatus for performing the process or method efficiently for high volume manufacturing.

### SUMMARY

Embodiments of the invention provide a method of forming patterns including magnetic and non-magnetic domains on a magnetically susceptible surface of one or more substrates. In one embodiment, a method of forming a pattern of magnetic domains on a magnetically susceptible material disposed on a substrate includes exposing a first portion of a magnetically susceptible layer to a plasma formed from a gas mixture, wherein the gas mixture includes at least a halogen containing gas and a hydrogen containing gas for a time sufficient to modify a magnetic property of the first portion of the magnetically susceptible layer exposed through a mask layer from a first state to a second state.

In another embodiment, a method of forming a magnetic medium for a hard disk drive includes transferring a substrate having a magnetically susceptible layer and a patterned mask layer disposed on the magnetically susceptible layer into a processing chamber, wherein the patterned mask layer defines a first region unprotected by the mask layer and a second region protected by the mask layer, modifying a magnetic property of the first portion of the magnetically susceptible layer unprotected by the mask layer in the processing chamber, wherein modifying the magnetic property of the first portion of the magnetically susceptible layer further includes supplying a gas mixture into the processing chamber, wherein the gas mixture includes at least BF₃ gas and B₂H₆ gas, applying a RF power to the gas mixture to dissociate the gas mixture into reactive ions, and implanting boron ions from the dissociated gas mixture into the first region of the magnetically susceptible layer while forming a protection layer on the substrate surface.

In yet another embodiment, an apparatus for forming a magnetic medium for a hard disk drive includes a processing chamber utilized to modify a magnetic property of a first portion of a magnetically susceptible layer, wherein the processing chamber including a substrate support assembly disposed in the processing chamber, a gas supply source configured to supply a gas mixture including at least a halogen containing gas and a hydrogen containing gas to a surface of the substrate disposed on the substrate support assembly in the processing chamber, and a RF power coupled to the processing chamber having sufficient power to dissociate the gas mixture supplied into the processing chamber and implant ions dissociated from the gas mixture into the substrate surface, wherein the ions implanted into the substrate surface demagnetizing a first portion of the magnetically susceptible layer disposed on the substrate.

### BRIEF DESCRIPTION OF THE DRAWINGS

So that the manner in which the above-recited features of the present invention can be understood in detail, a more particular description of the invention, briefly summarized above, may be had by reference to embodiments, some of which are illustrated in the appended drawings.

FIG. 1 depicts one embodiment of a plasma immersion ion implantation tool suitable for practice one embodiment of the present invention;

FIG. 2 depicts a flow diagram illustrating a method for plasma immersion ion implantation process according to one embodiment of the present invention; and

FIGS. 3A-3C are schematic side views of a substrate at various stages of the method of FIG. 2.

To facilitate understanding, identical reference numerals have been used, where possible, to designate identical elements that are common to the figures. It is contemplated that elements disclosed in one embodiment may be beneficially utilized on other embodiments without specific recitation.

It is to be noted, however, that the appended drawings illustrate only typical embodiments of this invention and are therefore not to be considered limiting of its scope, for the invention may admit to other equally effective embodiments.

### DETAILED DESCRIPTION

Embodiments of the invention generally provide apparatus and methods of forming magnetic and non-magnetic regions on magnetic media substrates for hard disk drives. The apparatus and methods include modifying the magnetic properties of the substrate by applying a plasma immersion ion implantation process to implant ions into the substrate in a patterned manner to create magnetic and non-magnetic domains with different magnetic properties detectable by a magnetic head. The magnetic domains are separately addressable by a magnetic head held in proximity to the substrate surface, enabling the magnetic head to detect and affect the magnetic properties of an individual magnetic domain. Embodiments of the invention include forming magnetic and non- magnetic domains on a substrate for hard disk drives while preserving the topography of the substrate.

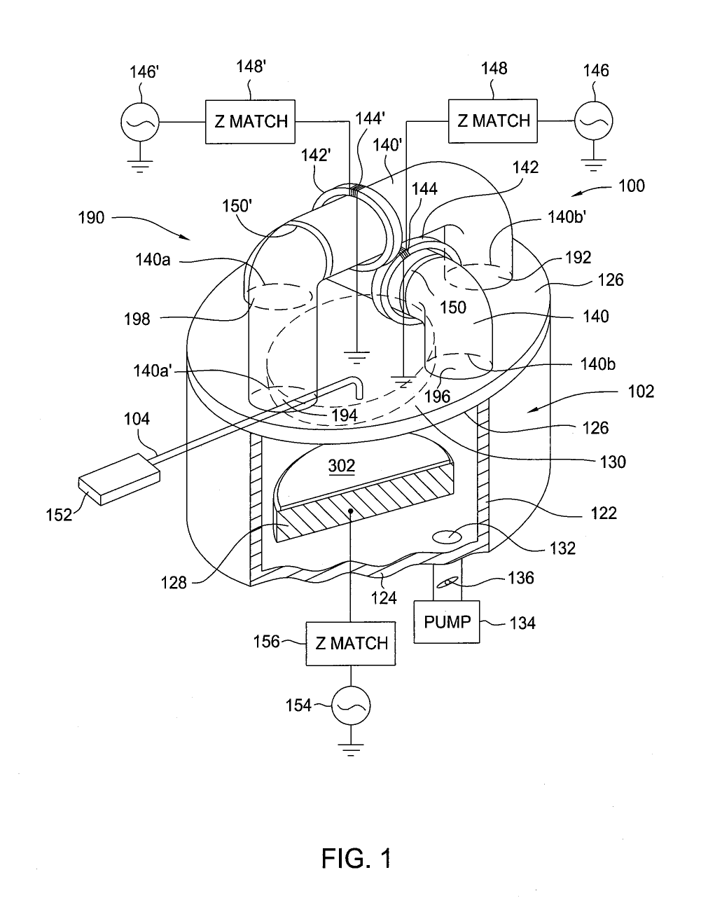

FIG. 1 is an isometric drawing of a plasma immersion ion implantation chamber that may be utilized to practice embodiments of the present invention. The chamber of FIG. 1 is useful for performing plasma immersion ion implantation procedures, but may also be used to shower a substrate with energetic ions without implanting. The processing chamber 100 includes a chamber body 102 having a bottom 124, a top 126, and side walls 122 enclosing a process region 104. A substrate support assembly 128 is supported from the bottom 124 of the chamber body 102 and is adapted to receive a substrate 302 for processing. In one embodiment, the substrate support assembly 128 may include an embedded heater element or cooling element (not shown) suitable for controlling the temperature of the substrate 302 supported on the substrate support assembly 128. In one embodiment, the temperature of the substrate support assembly 128 may be controlled to prevent the substrate 302 from over heating during the plasma immersion ion implantation process so as to maintain the substrate 302 at a substantially constant temperature during the plasma immersion ion implantation process. The temperature of the substrate support assembly 128 may be controlled between about 30 degrees Celsius to about 200 degrees Celsius.

A gas distribution plate 130 is coupled to the top 126 of the chamber body 102 facing the substrate support assembly 128. A pumping port 132 is defined in the chamber body 102 and coupled to a vacuum pump 134. The vacuum pump 134 is coupled through a throttle valve 136 to the pumping port 132. A process gas source 152 is coupled to the gas distribution plate 130 to supply gaseous precursor compounds for processes performed on the substrate 302.

The chamber 100 depicted in FIG. 1 further includes a plasma source 190. The plasma source 190 includes a pair of separate external reentrant conduits 140, 140′ mounted on the outside of the top 126 of the chamber body 102 disposed transverse or orthogonal to one another. The first external conduit 140 has a first end 140a coupled to an opening 198 formed in the top 126 and is in communication with a first side of the process region 104 in the chamber body 102. A second end 140b has an opening 196 coupled to the top 126 and is in communication with a second side of the process region 104. The second external reentrant conduit 140b has a first end 140a′ having an opening 194 coupled to the top 126 and in communication with a third side of the process region 104. A second end 140b′ having an opening 192 of the second external reentrant conduit 140b is coupled to the top 126 and is in communication with a fourth side of the process region 104. In one embodiment, the first and second external reentrant conduits 140, 140′ are configured to be orthogonal to one another, thereby providing the two ends 140a, 140a′, 140b, 140b′ of each external reentrant conduits 140, 140′ orientated at about 90 degree intervals around the periphery of the top 126 of the chamber body 102. The orthogonal configuration of the external reentrant conduits 140, 140′ allows a plasma source distributed uniformly across the process region 104. It is contemplated that the first and second external reentrant conduits 140, 140′ may have other configurations utilized to control plasma distribution in the process region 104.

Magnetically permeable torroidal cores 142, 142′ surround a portion of a corresponding one of the external reentrant conduits 140, 140′. The conductive coils 144, 144′ are coupled to respective RF power sources 146, 146′ through respective impedance match circuits or elements 148, 148′. Each external reentrant conduits 140, 140′ is a hollow conductive tube interrupted by an insulating annular ring 150, 150′ respectively that interrupts an otherwise continuous electrical path between the two ends 140a, 140b (and 140a′, 104b′) of the respective external reentrant conduits 140, 140′. Ion energy at the substrate surface is controlled by an RF bias generator 154 coupled to the substrate support assembly 128 through an impedance match circuit or element 156.

Process gases including gaseous compounds supplied from the process gas source 152 are introduced through the overhead gas distribution plate 130 into the process region 104. RF power source 146 is coupled from the power applicators, i.e., core and coil, 142, 144 to gases supplied in the conduit 140, which creates a circulating plasma current in a first closed torroidal path power source 146′ may be coupled from the other power applicators, i.e., core and coil, 142′, 144′ to gases in the second conduit 140′, which creates a circulating plasma current in a second closed torroidal path transverse (e.g., orthogonal) to the first torroidal path. The second torroidal path includes the second external reentrant conduit 140′ and the process region 104. The plasma currents in each of the paths oscillate (e.g., reverse direction) at the frequencies of the respective RF power sources 146, 146′, which may be the same or slightly offset from one another.

In operation, a process gas mixture is provided to the chamber from the process gas source 152. Depending on the embodiment, the process gas mixture may comprise inert or reactive gases to be ionized and directed toward the substrate 302. Virtually any gas that may be easily ionized can be used in the chamber 100 to practice embodiments of the invention. Some inert gases that may be used include helium, argon, neon, krypton, and xenon. Reactive or reactable gases that may be used include borane and its oligomers, such as diborane, phosphine and its oligomers, arsine, nitrogen containing gases, halogen containing gas, hydrogen containing gases, oxygen containing gases, carbon containing gases, and combinations thereof. In some embodiments, nitrogen gas, hydrogen gas, oxygen gas, and combinations thereof may be used. In other embodiments, ammonia and its derivatives, analogues, and homologues, may be used, or hydrocarbons such as methane or ethane may be used. In still other embodiments, halogen containing gases, such as fluorine or chlorine containing gases like BF₃, may be used. Any substance that may be readily vaporized, and that does not deposit a material substantially identical to the magnetically susceptible layer of the substrate, may be used to modify its magnetic properties through bombardment or plasma immersion ion implantation. Most hydrides may be used, such as silane, borane, phosphine, diborane (B₂H₆), methane, and other hydrides. Also, carbon dioxide and carbon monoxide may be used.

The power of each RF power source 146, 146′ is operated so that their combined effect efficiently dissociates the process gases supplied from the process gas source 152 and produces a desired ion flux at the surface of the substrate 302. The power of the RF bias generator 154 is controlled at a selected level at which the ion energy dissociated from the process gases may be accelerated toward the substrate surface and implanted at a desired depth below the top surface of the substrate 302 in a desired ion concentration. For example, with relatively low RF power of about 100 W would give ion energy of about 200 eV. Dissociated ions with low ion energy may be implanted at a shallow depth between about 1 Å and about 500 Å from the substrate surface. Alternatively, high bias power of about 5000 W would give ion energy of about 6 keV. The dissociated ions with high ion energy provided and generated from high RF bias power, such as higher than about 100 eV, may be implanted into the substrate having a depth substantially over 500 Å depth from the substrate surface. In one embodiment, the bias RF power supplied to the chamber may be between about 100 Watts and about 7000 Watts, which equates to ion energy between about 100 eV and about 7 keV.

Whereas disrupting the alignment of atomic spins in selected portions of the magnetic layer is desired, ion implant with relatively high energy, such as between about 200 eV and about 5 keV, or between about 500 eV and about 4.8 keV, such as between about 2 keV and about 4 keV, for example about 3.5 keV, may be useful. The combination of the controlled RF plasma source power and RF plasma bias power dissociates electrons and ions in the gas mixture, imparts a desired momentum to the ions, and generates a desired ion distribution in the processing chamber 100. The ions are biased and driven toward the substrate surface, thereby implanting ions into the substrate in a desired ion concentration, distribution and depth from the substrate surface. In some embodiments, ions may be implanted at a concentration between about 10¹⁸ atoms/cm³ and about 10²³ atoms/cm³ at a depth ranging from about 1 nm to about 100 nm, depending on the thickness of the magnetic layer.

Plasma immersion implanting ions deeply in the magnetic layer causes the most change in the magnetic properties of the implanted area. A shallow implant, such as 2-10 nm in a 100 nm thick layer, will leave a significant portion of the layer below the implanted area with atomic spin in alignment. Such a shallow implant with ions having energy between about 200 eV and about 1,000 eV will cause a partial change to the magnetic properties. Thus, the degree of change may be selected by tuning the depth of the implant. The size of ion being implanted will also affect the energy needed to implant ions to a given depth. For example, helium ions implanted into a magnetic material at an average energy of about 200 eV will demagnetize the magnetic material by about 20% to about 50%, and argon ions implanted at an average energy of about 1,000 eV will demagnetize the magnetic material by about 50% to about 80%.

It is noted that the ions provided in a plasma immersion ion implantation process, as described herein, are generated from a plasma formed by applying a high voltage RF or any other forms of EM field (microwave or DC) to a processing chamber. The plasma dissociated ions are then biased toward the substrate surface and implanted into a certain desired depth from the substrate surface. The conventional ion implantation processing chamber utilizing ion guns or ion beams accelerates a majority of ions up to a certain energy resulting in implanting accelerated ions into a certain deeper region of the substrate, as compared to the ions implanted by the plasma immersion ion implantation process. The ions provided in the plasma immersion ion implantation process do not generally have a beam-like energy distribution as the ions in conventional beamliners. Due to several factors, such as ion collisions, process time and process space and varying intensity of accelerating plasma field, a significant fraction of plasma ions have an energy spread down close to zero ion energy. Accordingly, the ion concentration profile formed in the substrate by a plasma immersion ion implantation process is different from the ion concentration profile formed in the substrate by a conventional ion implantation processing chamber, wherein the ions implanted by the plasma immersion ion implantation process is mostly distributed close to the surface of the substrate while the ions implanted by the conventional ion implantation processing chamber. Furthermore, the energy required to perform a plasma immersion ion implantation process is less than the energy required to operate an ion gun (or an ion beam) ion implantation process. The higher energy required from the conventional ion gun (or an ion beam) ion implantation process can provide ions with higher implantation energy to penetrate into a deeper region from the substrate surface. In contrast, the plasma immersion ion implantation process utilizing RF power to plasma dissociate ions for implanting requires less energy to initiate the plasma immersion ion implantation process so that the ions generated from the plasma can be efficiently controlled and implanted into a relatively shadow depth from the substrate surface. Accordingly, plasma immersion ion implantation process provides an economical efficient ion implantation process, as compared to the conventional ion gun/beam ion implantation process, to implant ions into a substrate surface at desired depth with less energy and manufacture cost.

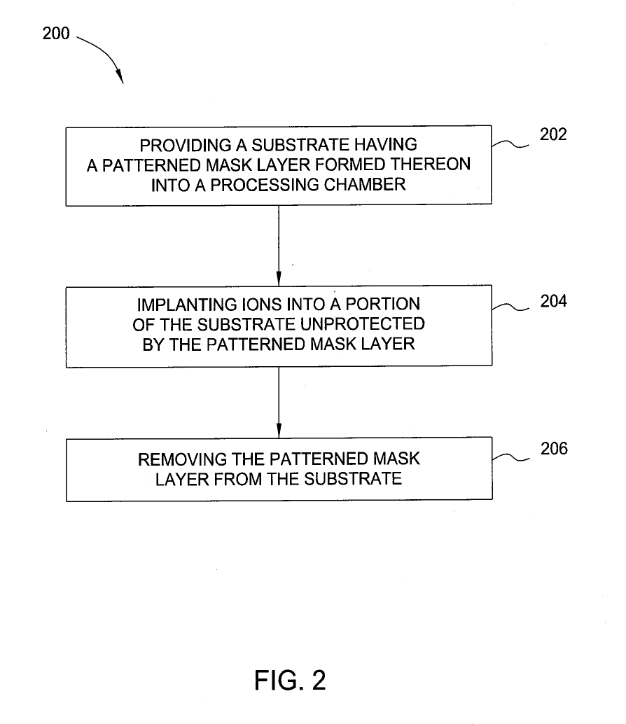

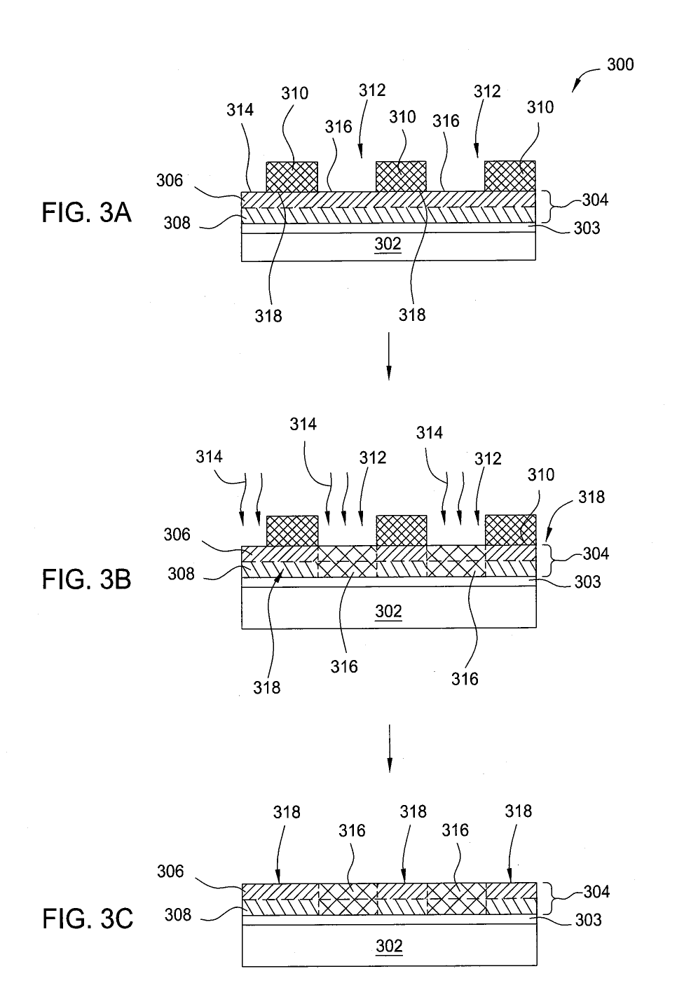

FIG. 2 depicts a flow diagram illustrating a process 200 for a plasma immersion ion implantation process according to one embodiment of the present invention. FIGS. 3A-3C are schematic cross-sectional views of the substrate 302 at various stages of the process of FIG. 2. The process 200 is configured to be performed in a plasma immersion ion implantation processing chamber, such as the processing chamber 100 as described in FIG. 1. It is contemplated that the process 200 may be performed in other suitable plasma immersion ion implantation systems, including those from other manufacturers.

The process 200 begins at step 202 by providing a substrate, such as the substrate 302, in the processing system 100. In one embodiment, the substrate 301 be comprised of metal or glass, silicon, dielectric bulk material and metal alloys or composite glass, such as glass/ceramic blends. In one embodiment, the substrate 302 has a magnetically susceptible layer 304 disposed over a base layer 303. The base layer 303 is generally a structurally strong material such as metal, glass, ceramic, or a combination thereof. The base layer 303 provides structural strength and good adhesion to the magnetically susceptible layer 304, and is generally magnetically impermeable with diamagnetic, or only very weak paramagnetic properties. For example, in some embodiments, the magnetic susceptibility of the base layer 303 is below about 10⁻⁴ (the magnetic susceptibility of aluminum is about 1.2×10⁻⁵).

The magnetically susceptible layer 304 is generally formed from one or more ferromagnetic materials. In some embodiments, the magnetically susceptible layer 304 comprises a plurality of layers having the same or different composition. In one embodiment, the magnetically susceptible layer 304 comprises a first layer 308 and a second layer 306, wherein the first layer 308 is a soft magnetic material, which is generally defined as a material with low magnetic coercivity, and the second layer 306 has higher coercivity than the first layer 308. In some embodiments, the first layer 308 may comprise iron, nickel, platinum, or combinations thereof. In some embodiments, the first layer 308 may comprise a plurality of sub-layers (not shown) having the same or different compositions. The second layer 306 may also comprise a variety of materials, such as cobalt, chromium, platinum, tantalum, iron, terbium, gadolinium, or combinations thereof. The second layer 306 may also comprise a plurality of sub-layers (not shown) having the same or different compositions. In one embodiment, the magnetically susceptible layer 304 comprises a first layer 308 of iron or iron/nickel alloy having a thickness between about 100 nm and about 1,000 nm (1 μm) and a second layer 306 that comprises chromium, cobalt, platinum or combinations thereof, having a thickness between about 30 nm and about 70 nm, such as about 50 nm. The layers 306, 308 may be formed by any suitable method, such as physical vapor deposition, or sputtering, chemical vapor deposition, plasma-enhanced chemical vapor deposition, spin-coating, plating by electrochemical or electroless means, and the like.

A mask material 310 is applied to an upper surface 314 of the magnetically susceptible layer 304. The mask material 310 is patterned to form openings 312 to expose unmasked first portions 316 of the underlying magnetically susceptible layer 304 for processing. The mask material 310 protects the second portions 318 of the underlying magnetically susceptible layer 304 masked from being processed. Thus, the mask layer 310 defines masked and unmasked portions 318, 316 of the magnetically susceptible layer 304 so as to form domains of varying magnetic activity after further processing. The mask layer 310 generally comprises a material that can be readily removed without altering the magnetically susceptible layer 304, or a material that will not adversely affect the device properties if it is not removed. For example, in many embodiments, the mask layer 310 is soluble in a solvent liquid, such as water or hydrocarbon. In some embodiments, the mask layer 310 is applied to the substrate as a curable liquid, patterned by physical imprint with a template, and cured by heating or UV exposure. The mask layer 310 is also resistant to degradation by incident energy or energetic ions. In some embodiments, the mask layer 310 is a curable material, such as an epoxy or thermoplastic polymer, that will flow prior to being cured and will provide some resistance to energetic processes after curing.

The mask layer 310 may leave the first portions 316 defined by the openings 312 completely exposed for processing and the second portions 318 covered with a thin or thick mask layer 310 to protect the second portions 318 from being processed. Accordingly, the mask layer 310 may keep some portions of the substrate 302 essentially unmasked, while the other portions are masked. The first portions 316 of the substrate 302 may then be exposed to energy to alter the magnetic properties of the unmasked portions 316. Upon removal of the mask layer 310, the substrate 302 is left with its original topography, but with a very fine pattern of magnetic and non-magnetic domains capable of supporting storage densities in excess of 1 Tb/in².

At step 204, a plasma immersion ion implantation process is performed to implant ions into the first portions 316 of the substrate 302 unprotected by the mask layer 310, as shown by the arrow 314 depicted in FIG. 3B. The plasma immersion ion implantation process may be performed to implant ions into unmasked regions 316 of the magnetically susceptible layer 304 to modify the magnetic properties of the magnetically susceptible layer 304. The ions 314 dissociated in the processing chamber 100 is directed toward the substrate 302, and impinges on the exposed unmasked portions 316 of the magnetically susceptible layer 304 defined by the openings 312 of the mask layer 310. Exposing the unmasked portions 316 of the magnetically susceptible layer 304 to plasma energy and dissociated ions will generally begin to disrupt and change the magnetic properties when the plasma energy and the dissociated ions reach sufficient intensity to stimulate thermal motion of the atoms in the magnetically susceptible layer 304. Energy above a certain threshold and the dissociated ions implanted into the magnetically susceptible layer 304 will randomize the spin direction of the atoms, reducing or eliminating the magnetic properties of the material. Magnetic susceptibility is the ease with which a material will acquire magnetism when exposed to a magnetic field. Modification of the unmasked portions 316 of the magnetically susceptible layer 304 creates a pattern of domains defined by the unmodified zones 318 (protected by the mask layer 310) and the modified zones 316 (unprotected by the mask layer 310). The pattern may be recognized as unmodified domains 318 of magnetic material and modified domains 316 of the non-magnetic material, or unmodified domains 318 of high magnetic field and modified domains 316 of low magnetic field, or unmodified domains 318 of high magnetic susceptibility and modified domains 316 of low magnetic susceptibility. Accordingly, by choosing a proper range of plasma energy to implant suitable ion species with a desired amount into the magnetically susceptible layer 304, the magnetic properties of the magnetically susceptible layer 304 can be efficiently reduced, eliminated or changed to form desired magnetic and non-magnetic domains 318, 316 on the substrate 302.

The dopants/ions impinging into the magnetically susceptible layer 304 may change the magnetic properties of the magnetically susceptible layer 304. For example, implanted ions, such as boron, phosphorus, and arsenic ions, will not only randomize magnetic moments near the implant sites, but also impart their own magnetic properties to the surface, resulting in changed magnetic properties, such as demagnetizing of the magnetically susceptible layer, for the implanted region. Furthermore, the thermal energy or other types of energy provided during the ion impinging or plasma bombardment process may transfer kinetic energy of the energetic ions to the magnetic surface, thereby inducing differential randomization of magnetic moments with each collision, thereby changing the magnetic properties and demagnetizing of the magnetically susceptible layer 304 as well. In one embodiment, the magnetism or the magnetic susceptibility of the magnetically susceptible layer 304 may be reduced and/or eliminated by exposure and bombardment to a gas mixture comprising at least a halogen containing gas and a hydrogen containing gas. It is believed that the halogen containing gas supplied in the gas mixture can slightly etch the surface of the unmasked region 316, facilitating penetration dopants into the magnetically susceptible layer 304. At the same time, the hydrogen containing gas supplied in the gas mixture may assist forming a thin repairing layer on the etched surface attacked by the halogen containing gas, thereby maintaining the overall thickness and topography of the magnetically susceptible layer 304 remained unchanged.

In one embodiment, suitable examples of the halogen containing gas supplied in the gas mixture include BF₃, BCl₃, CF₄, SiF₄ and the like. Suitable examples of the hydrogen containing gas supplied in the gas mixture include BH₃, B₂H₆, P₂H₅, PH₃, CH₄, SiH₄ and the like. For example, in an embodiment wherein BF₃ gas is utilized as the halogen containing gas supplied in the gas mixture during the plasma immersion ion implantation process, the BF₃ gas is dissociated by the RF energy supplied into the processing chamber, forms fluorine active species and boron active species. It is believed that the fluorine active species will slightly etch the surface of the magnetically susceptible layer 304 unprotected by the mask layer 310 while incorporating the boron species into the magnetically susceptible layer 304 which modifies the magnetic properties of the unmasked region 316 of the magnetically susceptible layer 304. The implanted boron elements may randomize the spin direction of the atoms in the unmasked region 316 of the magnetically susceptible layer 304, reducing and/or eliminating the magnetic properties of the magnetically susceptible layer 304, thereby forming a non-magnetic domain 316 in the magnetically susceptible layer 304. The hydrogen active species provided by the hydrogen containing gas supplied in the gas mixture may assist repairing dangling bonds formed by the attack of the fluorine active species, thereby assisting smoothing of the surface of the implanted regions 316 unprotected by the mask layer 310. Therefore, the hydrogen containing gas supplied during the plasma immersion ion implantation process may efficiently provide a thin layer of protection layer on the substrate surface, thereby assisting implanting ions into the substrate without adversely changing or damaging the topography of the substrate surface. It is noted that the thin protection layer may not be a permanently deposited layer and may be etched or cleaned away as needed to assist good control of the surface topography of the magnetically susceptible layer 304.

In one embodiment, the ions dissociated from the gas mixture may be implanted into the magnetically susceptible layer 304 to a depth of at least about 50% of the overall thickness of the magnetically susceptible layer 304. In one embodiment, the ions are implanted to a depth of between about 5 nm and about 30 nm from the substrate surface. In the embodiment wherein the magnetically susceptible layer 304 is in the form of two layers, such as the first layer 306 and the second layer 308, the ions may be substantially implanted into the first layer 306, such as to a depth between about 2 nm and about 17 nm from the substrate surface of the magnetically susceptible layer 304.

In one embodiment, the gas mixture supplied during processing may further include an inert gas. Suitable examples of the inert gas include N₂, Ar, He Xe, Kr and the like. The inert gas may promote the ion bombardment in the gas mixture, thereby increasing the probability of process gas collision, thereby resulting in reduced recombination of ion species.

A RF power, such as capacitive or inductive RF power, DC power, electromagnetic energy, or magnetron sputtering, may be supplied into the processing chamber 100 to assist dissociating gas mixture during processing. Ions generated by the dissociative energy may be accelerated toward the substrate using an electric field produced by applying a DC or RF electrical bias to the substrate support or to a gas inlet above the substrate support, or both. In some embodiments, the ions may be subjected to a mass selection or mass filtration process, which may comprise passing the ions through a magnetic field aligned orthogonal to the desired direction of motion.

In one embodiment, the hydrogen containing gas in the gas mixture may be supplied into the processing chamber at a flow rate between about 10 sccm and about 500 sccm and the fluorine containing gas in the gas mixture may be supplied into the processing chamber at a flow rate between about 5 sccm and about 350 sccm. The chamber pressure is generally maintained between about 4 mTorr and about 100 mTorr, such as about 10 mTorr.

Ions, such as helium, hydrogen, oxygen, nitrogen, boron, phosphorus, arsenic, fluorine, silicon, platinum, aluminum, or argon, utilized to alter the magnetic properties of a substrate surface may be generated during the plasma dissociation process during the RF power generation process. The electric field provided by the RF power may be capacitively or inductively coupled for purposes of ionizing the atoms, and may be a DC discharge field or an alternating field, such as an RF field. Alternately, microwave energy may be applied to a precursor gas containing any of these elements to generate ions. In one embodiment, ion energy less than 5 keV is utilized for magnetic medium implant, such as between about 0.2 keV and about 4.8 keV, for example about 3.5 keV. In some embodiments, the gas containing energetic ions may be a plasma. An electrical bias of between about 50 V and about 500 V is applied to the substrate support, the gas distributor, or both, to accelerate the ions toward the substrate support with the desired energy. In some embodiments, the electrical bias is also used to ionize the process gas. In other embodiments, a second electric field is used to ionize the process gas. In one embodiment, a high-frequency RF field and a low-frequency RF field are provided to ionize the process gas and bias the substrate support. The high-frequency field is provided at a frequency of 13.56 MHz and a power level between about 200 W and about 5,000 W, and the low-frequency field is provided at a frequency between about 1,000 Hz and about 10 kHz at a power level between about 50 W and about 200 W. Energetic ions may be generated by an inductively coupled electric field by providing a recirculation pathway through an inductive coil powered by RF power between about 50 W and about 500 W. The ions thus produced will generally be accelerated toward the substrate by biasing the substrate or a gas distributor as described above.

In some embodiments, generation of ions may be pulsed. Power may be applied to the plasma source for a desired time, and then discontinued for a desired time. Power cycling may be repeated for a desired number of cycles at a desired frequency and duty cycle. In many embodiments, the plasma may be pulsed at a frequency between about 0.1 Hz and about 1,000 Hz, such as between about 10 Hz and about 500 Hz. In other embodiments, the plasma pulsing may proceed with a duty cycle (ratio of powered time to unpowered time per cycle) between about 10% and about 90%, such as between about 30% and about 70%.

At step 206, after the plasma immersion ion implantation process is completed, the mask layer 310 is then removed from the substrate surface, leaving the substrate with the magnetically susceptible layer 304 having a pattern of domains defined by unmodified regions 318 (e.g., magnetic domain) and modified regions 316 (e.g., non-magnetic domain), wherein the modified regions 316 have lower magnetic activity than the unmodified regions 318, as shown in FIG. 3C. The mask layer 310 may be removed by etching with a chemistry that does not react with the underlying magnetic materials, such as a dry cleaning or ashing process, or by dissolving in a liquid solvent, such as DMSO. In one example, due to the absence of permanent deposition on the magnetically susceptible layer 304, topography of the magnetically susceptible layer 304 after patterning is substantially identical to its topography before patterning.

A substrate having a magnetically susceptible layer disposed thereon is provided to a processing chamber, such as the processing chamber 100 depicted in FIG. 1. The substrate prepared by the process described above with referenced to FIG. 2 is subjected to a plasma formed from a gas mixture containing boron and fluorine ions provided BF₃ gas and hydrogen ions provided by B₂H₆ gas. The process chamber pressure is maintained at about 15 mTorr, the RF bias voltage is about 9 keV, the source power is about 500 Watts, the BF₃ gas is provided at a flow rate of about 30 sccm and the B₂H₆ gas is provided at a flow rate of about 30 sccm and the implant time is about 40 seconds. Boron ions were found to penetrate the magnetically susceptible layer up to a depth of about 20 nm. Argon gas may also be used in this example to supplement plasma formation.

Accordingly, processes and apparatus of forming patterns including magnetic and non-magnetic domains on a magnetically susceptible surface on a substrate are provided. The process advantageously provides a method to modify magnetic properties of a substrate by a plasma immersion ion implantation process in a patterned manner to create magnetic and non-magnetic domains with different magnetic properties while preserving the topography of the substrate.

While the foregoing is directed to embodiments of the invention, other and further embodiments of the invention may be devised without departing from the basic scope thereof.

What is claimed is:

1. A method of forming a pattern of magnetic domains on a magnetically susceptible material disposed on a substrate, comprising:
exposing a first portion of a magnetically susceptible layer to a plasma formed from a gas mixture for a time sufficient to modify a magnetic property of the first portion of the magnetically susceptible layer exposed through a mask layer from a first state to a second state, wherein the gas mixture includes at least a halogen containing gas and a hydrogen containing gas.

2. The method of claim 1, wherein halogen containing gas is selected from a group consisting of BF₃, BCl₃, CF₄ and SiF₄.

3. The method of claim 1, wherein the hydrogen containing gas is selected from a group consisting of BH₃, B₂H₆, P₂H₅, PH₃, CH₄ and SiH₄.

4. The method of claim 1, wherein the halogen containing gas is BF₃ and the hydrogen containing gas is B₂H₆.

5. The method of claim 1, wherein exposing further comprises:
implanting ions dissociated in the plasma into the first portion of the magnetically susceptible layer.

6. The method of claim 5, wherein exposing further comprises:
forming a protection layer on the first portion while implanting.

7. The method of claim 1, wherein the magnetically susceptible layer includes a first layer disposed on a second layer.

8. The method of claim 7, wherein the first layer is selected from a group consisting of iron, nickel, platinum, or combinations thereof, and the second layer is selected from a group consisting of cobalt, chromium, platinum, tantalum, iron, terbium, gadolinium, or combinations thereof.

9. The method of claim 1, wherein exposing further comprises:
providing the gas mixture to the substrate surface disposed on a substrate support assembly disposed in a processing chamber;
applying energy to the gas mixture to ionize at least a portion of the gas mixture; and
implanting ions dissociated in the plasma into the first portion of the magnetically susceptible layer.

10. The method of claim 9, wherein implanting ions dissociated in the plasma into the first portion of the magnetically susceptible layer further comprises substantially demagnetizing the first portion of the magnetically susceptible layer.

11. A method of forming a magnetic medium for a hard disk drive, comprising:
transferring a substrate having a magnetically susceptible layer and a patterned mask layer disposed on the magnetically susceptible layer into a processing chamber, wherein the patterned mask layer defines a first region unprotected by the mask layer and a second region protected by the mask layer; and
modifying a magnetic property of the first portion of the magnetically susceptible layer unprotected by the mask layer in the processing chamber, wherein modifying the magnetic property of the first portion of the magnetically susceptible layer further comprises:
supplying a gas mixture into the processing chamber, wherein the gas mixture includes at least a BF₃ gas and a B₂H₆ gas;
applying a RF power to the gas mixture to dissociate the gas mixture into reactive ions; and
implanting boron ions dissociated from the gas mixture into the first region of the magnetically susceptible layer while forming a protection layer on the substrate surface.

12. The method of claim 11, wherein modifying the magnetic properties of first region of the magnetically susceptible layer comprises substantially demagnetizing the first region of the magnetically susceptible layer.

13. The method of claim 11, wherein modifying the magnetic properties of the magnetically susceptible layer comprises implanting ions to a depth of at least 50 percent of the thickness of the magnetically susceptible layer.

14. The method of claim 11, wherein the magnetically susceptible layer includes a first layer disposed on a second layer, wherein the first layer is selected from a group consisting of iron, nickel, platinum, or combinations thereof and the second layer is selected from a group consisting of cobalt, chromium, platinum, tantalum, iron, terbium, gadolinium, or combinations thereof.

15. An apparatus for forming a magnetic medium for a hard disk drive, comprising:
a processing chamber operable to modify a magnetic property of a first portion of a magnetically susceptible layer disposed on a substrate;
a substrate support assembly disposed in the processing chamber having a substrate supporting surface;
a gas supply source configured to supply a gas mixture including at least a halogen containing gas and a hydrogen containing gas to the processing chamber; and
a RF power coupled to the processing chamber having sufficient power to dissociate the gas mixture supplied into the processing chamber and implant ions dissociated from the gas mixture into a surface of the substrate disposed on the substrate support assembly.

16. The apparatus of claim 15, wherein the halogen containing gas is a BF₃ gas and the hydrogen containing gas is a B₂H₆ gas.

17. The apparatus of claim 16, wherein the magnetically susceptible layer includes a first layer disposed on a second layer, wherein the first layer is selected from a group consisting of iron, nickel, platinum, or combinations thereof and the second layer is selected from a group consisting of cobalt, chromium, platinum, tantalum, iron, terbium, gadolinium, or combinations thereof.

18. The apparatus of claim 17, wherein the substrate further comprises a patterned mask layer disposed on the magnetically susceptible layer defining the first region and a second region, wherein the dissociated ions are implanted into the first region protected by the patterned mask layer.

19. The apparatus of claim 17, wherein the ions are implanted through at least 50 percent of the thickness of the magnetically susceptible layer.
